(19) United States
(12) Patent Application Publication
(10) Pub. No.: US 2016/0132063 A1
(43) Pub. Date: May 12, 2016

(54) FEEDBACK SEPARATED CIRCUIT AND METHOD FOR DETECTING AN ARRANGEMENT OF MOTHER BOARD AND DAUGHTER BOARD

(71) Applicant: SHENZHEN CHINA STAR OPTOELECTRONICS TECHNOLOGY CO. LTD., Shenzhen (CN)

(72) Inventor: Xinhong CHEN, Shenzhen (CN)

(21) Appl. No.: 14/416,444

(22) PCT Filed: Dec. 29, 2014
(86) PCT No.: PCT/CN2014/095341

§ 371 Date: Jan. 22, 2015

(30) Foreign Application Priority Data
Nov. 5, 2014 (CN) 201410621063.9

(51) Int. Cl. G05F 1/46; G01R 19/165; G01R 31/28

(52) U.S. Cl. CPC G05F 1/46; G01R 31/2813; G01R 19/16566

(57) ABSTRACT

The present disclosure discloses a feedback separated circuit and a method for detecting a combination of mother board and daughter boards, said circuit comprising: a mother board, provided with a controller; and a plurality of daughter boards separated from said mother board, each daughter board being provided with a resistor having a different resistance, one end of each resistor being connected with one single feedback end of said controller, the other end of each resistor being connected with the ground. Through the circuit provided by the present disclosure, not only the combination mode between the mother board and the daughter boards can be recognized, but also the cost thereof is not increased.

### CROSS REFERENCE TO RELATED APPLICATION

The present application claims benefit of Chinese patent application CN 201410621063.9, entitled “Feedback Separated Circuit and Method for Detecting an Arrangement of Mother Board and Daughter Board” and filed on Nov. 5, 2014, which is incorporated herein by reference.

### FIELD OF THE INVENTION

The present disclosure relates to the field of electronic circuit, and particularly to a feedback separated circuit and a method for detecting a combination of mother board and daughter boards.

### BACKGROUND OF THE INVENTION

The current circuit board system generally comprises a mother board (also can be referred to as mother card, main card or main board), and a plurality of daughter boards. The mother board and the daughter boards each consist of a power layer, a ground layer, and a signal layer. Generally, the mother board is a passive board and is fixed in structure, while the daughter boards are movable and can be electrically connected with the mother board through connectors which can be inserted into and removed from the mother board.

When one mother board (the mother board A for example) of a circuit can be used with a plurality of daughter boards (such as the daughter boards a, b, c, . . . ), and said mother board is separated from the plurality of daughter boards, a problem would emerge. That is, it is unknown about how to determine the specific combination of the mother board and the corresponding daughter board, so that the mother board can sends correct signal to the daughter board in combination with the mother board at that time.

There are two methods for solving the aforesaid problem in the prior art.

According to the first method, for the circuit board system comprising a plurality of mother boards (such as the mother boards A1, A2, A3, . . . ), each mother board should be equipped with a corresponding daughter board according to a preset combination rule of the mother boards and the daughter boards (for example, A1-a, A2-b, . . . ). However, the mother boards and the daughter boards may be assembled incorrectly with this method, and the labor cost thereof is relatively high.

According to the second method, for the same mother board A, as shown in FIG. 1, a memory can be provided to each daughter board to be assembled with the mother board, such as the Electrically Erasable Programmable Read-Only Memory (EEPROM). When one of the daughter boards is energized, the mother board reads the data of the EEPROM, then determines the daughter board which is electrically connected with the mother board at that time, and thus outputs a corresponding voltage to the daughter board. The probability of error of this method is relatively low; however, since an EEPROM should be provided to each daughter board, the cost thereof would rise inevitably.

Therefore, how to determine the daughter board with which the mother board is connected currently without increasing the manufacturing cost thereof has become an effort demanding task in the industry.

### SUMMARY OF THE INVENTION

One of the technical problems to be solved by the present disclosure is to provide a feedback separated circuit which can detect the combination of the mother board and the daughter boards without increasing the cost thereof to a large extent. In addition, the present disclosure further provides a method for detecting the combination of the mother board and the daughter boards by means of said feedback separated circuit.

1) In order to solve the aforesaid technical problem, the present disclosure provides a feedback separated circuit, comprising: a mother board, provided with a controller; and a plurality of daughter boards separated from said mother board, each daughter board being provided with a resistor having a different resistance, one end of each resistor being connected with one single feedback end of said controller, the other end of each resistor being connected with the ground, wherein when one of the plurality of daughter boards is energized, the controller of said mother board compares a voltage of said feedback end with one of a plurality of voltage thresholds preset in said controller to determine the daughter board which is electrically connected with the mother board currently, and then output a corresponding voltage to said daughter board, the number of said voltage thresholds being equal to the number of said daughter boards.

2) In one preferred embodiment of item 1) of the present disclosure, said controller is preset with a protection voltage threshold, and said mother board performs voltage protection operation when the voltage of said feedback end is higher than or equal to said protection voltage threshold.

3) In one preferred embodiment of item 1) or item 2) of the present disclosure, said mother board is a system board and said daughter boards are different liquid crystal panels, and said mother board is provided with a resistor, one end of which is connected with the feedback end of said controller, and the other end of which is connected with a first set voltage.

4) In one preferred embodiment of any one of item 1) to item 3) of the present disclosure, the value of said first set voltage is 5V.

5) In one preferred embodiment of any one of item 1) to item 4) of the present disclosure, said protection voltage threshold is 5V.

6) In one preferred embodiment of any one of item 1) to item 5) of the present disclosure, said mother board is a distribution board, said controller is a driving Integrated Circuit (IC), and said daughter boards are different converters arranged in a backlight module of a liquid crystal display device, and said mother board is provided with a resistor string consisting of two resistors in series connection with each other, one end of said resistor string being connected with the ground, the other end of said resistor string being connected with a second set voltage, and a node of said resistor string through which the two resistors are connected being connected with a feedback end of said driving IC.

7) In one preferred embodiment of any one of item 1) to item 6) of the present disclosure, a resistance difference between every two adjacent resistors provided on the daughter boards is 10 KΩ.

8) According to another aspect of the present disclosure, the present disclosure further provides a method for detecting a combination of mother board and daughter boards using a feedback separated circuit, said method comprising the following steps: energizing one of the plurality of daughter boards; and comparing, by the controller of said mother board, a voltage of said feedback end with one of a plurality of voltage thresholds preset in said controller, so as to determine the daughter board which is electrically connected with the mother board currently, and then output a corresponding voltage to said daughter board.

9) In one preferred embodiment of item 8) of the present disclosure, further comprising performing, by said mother board, voltage protection operation when the controller of said mother board determines that the voltage of said feedback end is higher than or equal to a protection voltage threshold preset in said controller.

Compared with the prior art, one embodiment or a plurality of embodiments of the present disclosure may have the following advantages.

According to the circuit of the embodiment of the present disclosure, the feedback end of the mother board is connected with one end of the resistor of each daughter board, and the other end of each resistor is connected with the ground. When one of the daughter boards is energized, the voltage of the feedback end is detected, and then compared with the plurality of voltage thresholds preset in the mother board to determine the daughter board which is electrically connected with the mother board currently. Through the circuit of the embodiment of the present disclosure, not only the combination mode between the mother board and the daughter boards can be recognized, but also the cost thereof is not increased.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The accompanying drawings are used to provide further understandings of the present disclosure and constitute one part of the description. The drawings are used for interpreting the present disclosure together with the embodiments, not for limiting the present disclosure. In the drawings:

FIG. 1 schematically shows a circuit used for detecting the daughter board from the combination of the mother board and the daughter boards in the prior art;

FIG. 2 schematically shows a feedback separated circuit according to an embodiment of the present disclosure; and

FIG. 3 schematically shows a feedback separated circuit according to another embodiment of the present disclosure.

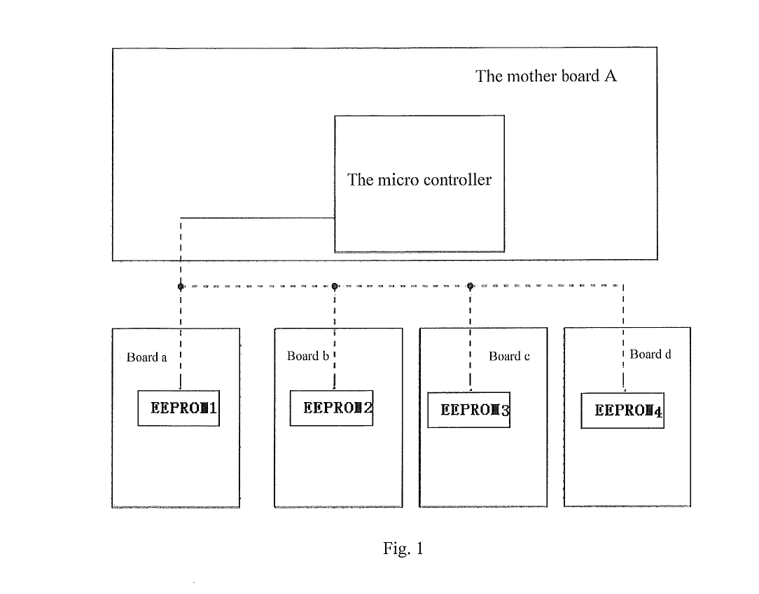

### DETAILED DESCRIPTION OF THE EMBODIMENTS

The present disclosure will be illustrated in detail hereinafter in combination with the accompanying drawings to make the purpose, technical solutions, and advantages of the present disclosure more clear.

### Embodiment 1

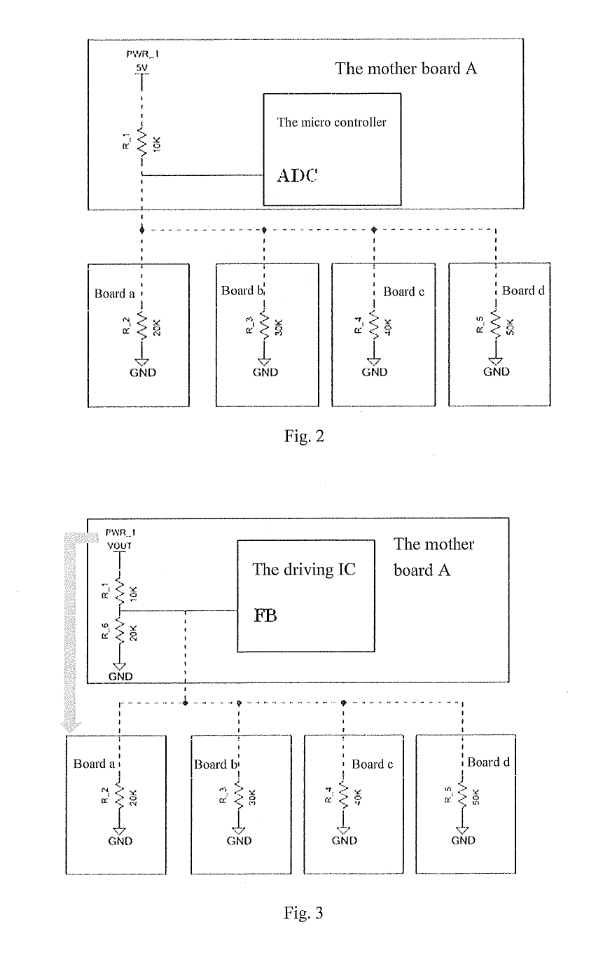

FIG. 2 schematically shows a feedback separated circuit according to an embodiment of the present disclosure. The components of the circuit and the connection relationship thereof will be illustrated in detail hereinafter with reference to FIG. 2.

It should be noted that, the present embodiment provides a circuit in which the daughter boards are the liquid crystal panels, and the mother board is a system board, for example. The circuit arrangement as shown in FIG. 2 enables the mother board to recognize liquid crystal panels with different resolutions and refresh rates (for example, the resolution thereof can be 1366×768 or 1920×1080, and the refresh rate thereof can be 60 Hz or 120 Hz), and thus output different voltages to different liquid crystal panels. Of course, the above is just an example, and the daughter boards can be arranged as other types of components by a person skilled in the art according to specific actual needs with reference to the present embodiment.

Reference can be made to FIG. 2, wherein a mother board A is provided with a resistor R_1, an electric potential of which is raised to a set voltage (for example, 5V). Each daughter board is provided with a resistor having a different resistance, and the electric potential of each resistor is reduced to a ground potential (GND). The mother board A is further provided with a micro controller having a feedback end, at which an Analog to Digital Converter (ADC) is arranged and connected with all the aforesaid resistors having the reduced ground potential.

The value of the resistor R_1, provided on the mother board A, is 10 KΩ. A resistance difference between every two adjacent resistors provided on the daughter boards is 10 KΩ. For example, the value of R_2, provided on the daughter board a, is 20 KΩ; the value of R_3, provided on the daughter board b, is 30 KΩ; the value of R_4, provided on the daughter board c, is 40 KΩ; and the value of R_5, provided on the daughter board d, is 50 KΩ. When one of the daughter boards is energized, said daughter board is electrically connected with the mother board A, and at this time the ADC of the micro controller of the mother board A has a voltage. Then, the micro controller of the mother board A compares the voltage of the ADC with one of a plurality of voltage thresholds preset in the micro controller, so as to determine the daughter board which is electrically connected with the mother board A at this moment, and thus output a corresponding voltage to said daughter board. The number of the voltage thresholds is equal to the number of the daughter boards. For example, when the mother board A is connected with four daughter boards, four voltage thresholds should be arranged corresponding to the four daughter boards respectively.

For example, when the daughter board c is connected with the mother board A, the voltage of the ADC of the micro controller is

$$5 V \times \frac{40 K}{10 K + 40 K} = 4 V .$$

The voltage thresholds preset in the micro controller of the mother board A include the voltage threshold of 4V, and thus the micro controller can determine, through comparison, that it is the daughter board c that is connected with the mother board A at this moment. Then, the mother board A outputs a corresponding voltage to the daughter board c.

In addition, the micro controller of the mother board A can be preset with a protection voltage threshold, for example, 5V. If the voltage of the ADC of the feedback end is higher than or equal to 5V, it can be determined that a poor connection exists between the mother board A and the daughter boards, and thus the mother board A can perform a corresponding voltage protection operation.

In summary, according to the circuit of the embodiment of the present disclosure, the feedback end of the mother board is connected with one end of the resistor of each daughter board, and the other end of each resistor is connected with the ground. When one of the daughter boards is energized, the voltage of the feedback end is detected, and then compared with the plurality of voltage thresholds preset in the mother board to determine the daughter board which is electrically connected with the mother board currently. Through the circuit of the embodiment, not only the combination mode between the mother board and the daughter boards can be recognized, but also the cost thereof is not increased.

### Embodiment 2

FIG. 3 schematically shows a feedback separated circuit according to another embodiment of the present disclosure. The components of the circuit and the connection relationship thereof will be illustrated in detail hereinafter with reference to FIG. 3.

It should be noted that, the present embodiment provides a circuit, in which the daughter boards are different converters arranged in a backlight module of a liquid crystal display device, and the mother board A is a system board, for example. Specifically, the mother board A is a distribution board, and is used for providing a corresponding voltage VOUT to each daughter board, which is the load of the mother board. Of course, the above is just an example, and the daughter boards can be arranged as other types of components by a person skilled in the art according to specific actual needs with reference to the present embodiment.

Reference can be made to FIG. 3, wherein each daughter board is provided with a resistor having a different resistance, and the electric potential of each resistor is reduced to a ground potential (GND). The mother board A is provided with a resistor string consisting of two resistors R_1 and R_6 in series connection with each other, the end of R_1 being connected with a voltage input end, and the end of R_6 being connected with the ground. A feedback end FB of a driving IC of the mother board A is connected with a node through which the two resistors R_1 and R_6 are connected.

When the mother board A is connected with different daughter boards, the feedback end FB of the driving IC of the mother board A is in parallel connection with different resistors. When one of the daughter boards is energized, the controller of the mother board detects the voltage of the feedback end, and then compares the voltage of the feedback end with the plurality of voltage thresholds preset in the mother board, so as to determine the daughter board which is electrically connected with the mother board currently. In this case, the mother board A can provide different voltages to different daughter boards.

The values of the resistors R_1 and R_6, which are provided on the mother board A, are 10 KΩ and 20 KΩ respectively. A resistance difference between every two adjacent resistors provided on the daughter boards is 10 KΩ. For example, the value of R_2, provided on the daughter board a, is 20 KΩ; the value of R_3, provided on the daughter board b, is 30 KΩ; the value of R_4, provided on the daughter board c, is 40 KΩ; and the value of R_5, provided on the daughter board d, is 50 KΩ. When one of the daughter boards is energized, said daughter board is electrically connected with the mother board A, and at this time the feedback end FB of the driving IC of the mother board A has a voltage. Then, the driving IC in the mother board A compares the voltage of the feedback end FB with one of a plurality of voltage thresholds preset in the driving IC, so as to determine the daughter board which is electrically connected with the mother board A at this moment. The number of the voltage thresholds is equal to the number of the daughter boards. For example, when the mother board A is connected with four daughter boards, and four voltage thresholds should be arranged corresponding to the four daughter boards respectively.

In addition, the driving IC of the mother board A can be preset with a protection voltage threshold. If the voltage of the feedback end FB is higher than or equal to the protection voltage threshold, it can be determined that a poor connection exists between the mother board A and the daughter boards, and thus the mother board A can perform a corresponding voltage protection operation.

According to the present embodiment, since the daughter boards are converters, the mother board A can recognize different regions through the aforesaid circuit, and thus different kinds of local dimming can be performed.

In summary, according to the circuit of the embodiment of the present disclosure, the feedback end of the mother board is connected with one end of the resistor of each daughter board, and the other end of each resistor is connected with the ground. When one of the daughter boards is energized, the voltage of the feedback end is detected, and then compared with the plurality of voltage thresholds preset in the mother board to determine the daughter board which is electrically connected with the mother board currently. Through the circuit of the embodiment, not only the combination mode between the mother board and the daughter boards can be recognized, but also the cost thereof is not increased.

The preferred embodiments of the present disclosure are stated hereinabove, but the protection scope of the present disclosure is not limited by this. Any changes or substitutes readily conceivable for any one skilled in the art within the technical scope disclosed by the present disclosure shall be covered by the protection scope of the present disclosure. Therefore, the protection scope of the present disclosure shall be determined by the scope as defined in the claims.

1. A feedback separated circuit, comprising:
a mother board, provided with a controller; and
a plurality of daughter boards separated from said mother board, each daughter board being provided with a resistor having a different resistance, one end of each resistor being connected with one single feedback end of said controller, the other end of each resistor being connected with the ground,
wherein when one of the plurality of daughter boards is energized, the controller of said mother board compares a voltage of said feedback end with one of a plurality of voltage thresholds preset in said controller to determine the daughter board which is electrically connected with the mother board currently, and then output a corresponding voltage to said daughter board, the number of said voltage thresholds being equal to the number of said daughter boards.

2. The feedback separated circuit according to claim 1, wherein said controller is preset with a protection voltage threshold, and said mother board performs voltage protection operation when the voltage of said feedback end is higher than or equal to said protection voltage threshold.

3. The feedback separated circuit according to claim 2, wherein said mother board is a system board and said daughter boards are different liquid crystal panels, and
said mother board is provided with a resistor, one end of which is connected with the feedback end of said controller, and the other end of which is connected with a first set voltage.

4. The feedback separated circuit according to claim 3, wherein the value of said first set voltage is 5V.

5. The feedback separated circuit according to claim 4, wherein said protection voltage threshold is 5V.

6. The feedback separated circuit according to claim 2, wherein said mother board is a distribution board, said controller is a driving IC, and said daughter boards are different converters arranged in a backlight module of a liquid crystal display device, and
said mother board is provided with a resistor string consisting of two resistors in series connection with each other, one end of said resistor string being connected with the ground, the other end of said resistor string being connected with a second set voltage, and a node of said resistor string through which the two resistors are connected being connected with a feedback end of said driving IC.

7. The feedback separated circuit according to claim 1, wherein a resistance difference between every two adjacent resistors provided on the daughter boards is 10 KΩ.

8. A method for detecting a combination of mother board and daughter boards using a feedback separated circuit, said feedback separated circuit comprising: a mother board, provided with a controller; and a plurality of daughter boards separated from said mother board, each daughter board being provided with a resistor having a different resistance, one end of each resistor being connected with one single feedback end of said controller, the other end of each resistor being connected with the ground,
said method comprising the following steps:
energizing one of the plurality of daughter boards; and
comparing, by the controller of said mother board, a voltage of said feedback end with one of a plurality of voltage thresholds preset in said controller, so as to determine the daughter board which is electrically connected with the mother board currently and then output a corresponding voltage to said daughter board, the number of said voltage thresholds being equal to the number of said daughter boards.

9. The method according to claim 8, further comprising:
performing, by said mother board, voltage protection operation when the controller of said mother board determines that the voltage of said feedback end is higher than or equal to a protection voltage threshold preset in said controller.
